(19) United States
(12) Patent Application Publication
(10) Pub. No.: US 2026/0033344 A1
(43) Pub. Date: Jan. 29, 2026

(54) GLASS SUBSTRATE FOR SEMICONDUCTORS

(71) Applicant: AGC Inc., Tokyo (JP)

(72) Inventors: Shinji UEKI, Tokyo (JP); Yoichiro SATO, Tokyo (JP); Kohei HORIUCHI, Tokyo (JP)

(73) Assignee: AGC Inc., Tokyo (JP)

(21) Appl. No.: 19/348,734

(22) Filed: Oct. 2, 2025

Related U.S. Application Data
(63) Continuation of application No. PCT/JP2023/044404, filed on Dec. 12, 2023.

(30) Foreign Application Priority Data
Apr. 6, 2023 (JP) 2023-061857

(51) Int. Cl. H01L 23/544; H01L 23/15; H01L 23/498

(52) U.S. Cl. CPC H01L 23/544; H01L 23/49827; H01L 23/15; H01L 2223/54433

(57) ABSTRACT

A glass substrate for semiconductors includes a first principal surface and a second principal surface disposed to face opposite the first principal surface, in which a wiring layer is to be formed on at least one of the first principal surface and the second principal surface. The glass substrate for semiconductors has a hole formed in at least one of the first principal surface and the second principal surface, and the glass substrate for semiconductors has an identification mark for identifying the glass substrate between the first principal surface and second principal surface. The minimum value of a shortest distance and a shortest distance is equal to or greater than 100 μm. A ratio (d1 ave/d2 ave) is 0.03-33. A ratio (d3 ave/d ave) is 0.01-0.50.

### INCORPORATION BY REFERENCE

This application is based upon and claims the benefit of priority from Japanese patent application No. 2023-061857, filed on Apr. 6, 2023, and PCT application No. PCT/JP2023/044404 filed on Dec. 12, 2023, the disclosure of which is incorporated herein in its entirety by reference.

### BACKGROUND

In recent years, there has been a progress in the development of a technique for mounting a plurality of semiconductor chips on an insulating substrate and electrically connecting the plurality of semiconductor chips. As insulating substrates, glass substrates and resin substrates have been studied. Glass substrates are superior in flatness, thermal stability, and insulation property compared to resin substrates. A glass substrate has a first principal surface and a second principal surface disposed to face opposite the first principal surface, and holes are formed in at least one of the first principal surface and the second principal surface. Electrodes are to be embedded in the holes, for example (see, for example, Japanese Unexamined Patent Application Publication No. 2018-188351, Japanese Patent No. 7014068, and Japanese Unexamined Patent Application Publication No. 2012-019106).

An identification mark is attached to a glass substrate. The identification mark is preferably formed inside the glass substrate, not on the surface of the glass substrate. This is because if a recess is formed as an identification mark on the surface of a glass substrate, dirt tends to accumulate in the recess. In addition, if the surface of a glass substrate is etched for the purpose of thickness adjustment, hole processing, or surface treatment after an identification mark is formed on the surface of the glass substrate, the identification mark will become indistinct. Japanese Unexamined Patent Application Publication No. 2017-178743 and Japanese Unexamined Patent Application Publication No. 2003-89553 disclose a technique for marking the inside of a glass substrate.

### SUMMARY

Since a glass substrate for semiconductors has holes formed thereto, it is prone to defects in the case where an identification mark is formed inside the glass substrate for semiconductors. The defects are, for example, fractures or cracks. The defects cause deterioration in the appearance of a glass substrate for semiconductors and the readability of an identification mark. Conventionally, there is room for improvement in the appearance of a glass substrate for semiconductors and the readability of an identification mark.

An embodiment of the present disclosure provides a technique for improving the appearance of a glass substrate for semiconductors and the readability of an identification mark.

A glass substrate for semiconductors according to an aspect of the present disclosure includes a first principal surface and a second principal surface disposed to face opposite the first principal surface, in which a wiring layer is to be formed on at least one of the first principal surface and the second principal surface. The glass substrate for semiconductors has a hole formed in at least one of the first principal surface and the second principal surface, and an identification mark for identifying the glass substrate between the first principal surface and the second principal surface. The minimum value (Lmin) of a shortest distance (L1) between the identification mark and a hole when the first principal surface is viewed from the front, and a shortest distance (L2) between the identification mark and the hole when the second principal surface is viewed from the front is equal to or greater than 100 μm. A ratio (d1 ave/d2 ave) of the average value (d1 ave) of the depth (d1) from the first principal surface to the identification mark to the average value (d2 ave) of the depth (d2) from the second principal surface to the identification mark is 0.03-33. A ratio (d3 ave/d ave) of the average value (d3 ave) of the thickness (d3) of identification mark to the average value (d ave) of the thickness (d) of the glass substrate is 0.01-0.50.

According to an aspect of the present disclosure, it is possible to improve the appearance of a glass substrate for semiconductors and the readability of an identification mark.

The above and other objects, features and advantages of the present disclosure will become more fully understood from the detailed description given hereinbelow and the accompanying drawings.

### BRIEF DESCRIPTION OF DRAWINGS

FIG. 1 is a plan view showing a first principal surface of a glass substrate according to an embodiment;

FIG. 2 is a plan view showing a second principal surface of a glass substrate according to an embodiment;

FIG. 3 is a cross-sectional view showing a glass substrate according to an embodiment;

FIG. 4 is a plan view showing an example of measuring points d; and

FIG. 5 is a plan view showing an example of an identification mark when the first principal surface is viewed from the front, in which an example of measuring points of d1, d2, and d3 is shown.

### DESCRIPTION OF EMBODIMENTS

Embodiments for implementing the present disclosure will be described below with reference to the drawings. In each of the drawings, the same or corresponding configurations are denoted by the same reference numerals, and explanations thereof may be omitted. In the specification, the symbol “-” used in the description of a numerical range indicates that a numerical range encompasses the numerical values falling before and after the symbol as the lower limit and upper limit of the numerical range.

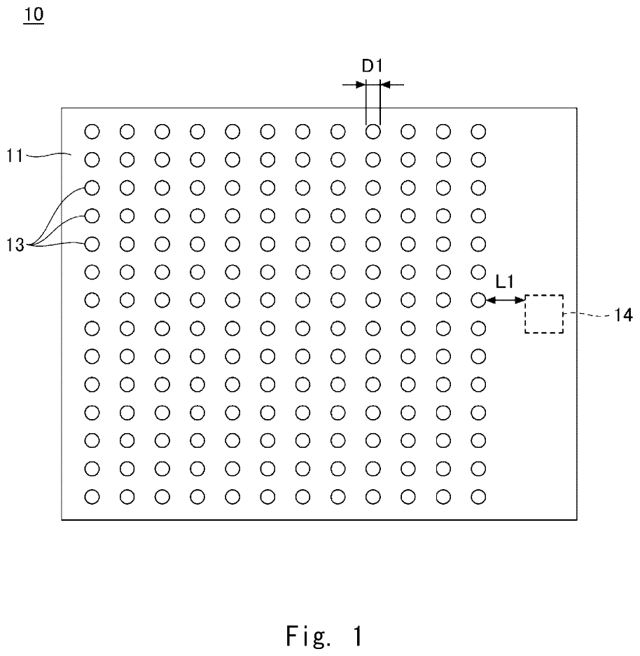

A glass substrate for semiconductors 10 according to an embodiment will be described with reference to FIGS. 1 to 5. Hereinafter, the glass substrate for semiconductors 10 will be simply referred to as the glass substrate 10. While the glass substrate 10 is used as a substrate for mounting semiconductors in this embodiment, it may also be used as a passive element substrate or a probe guard substrate.

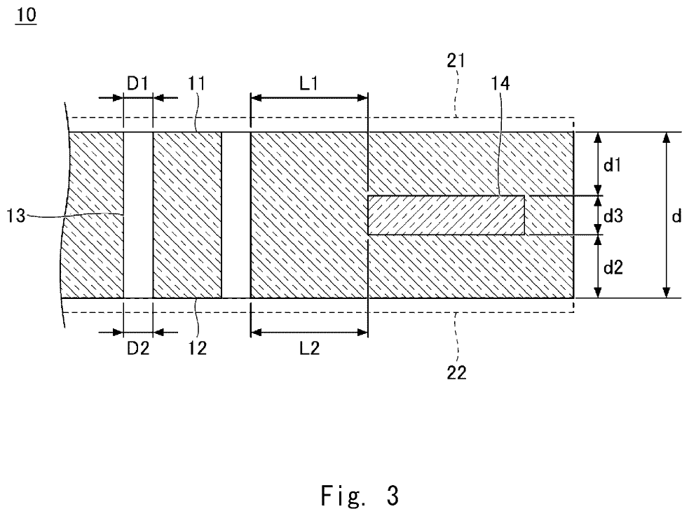

As shown in FIG. 3, the glass substrate 10 has a first principal surface 11 and a second principal surface 12 disposed to face opposite the first principal surface 11. Wiring layers 21 and 22 are to be formed on at least one of the first principal surface 11 and the second principal surface 12. The wiring layer 21 is formed on the first principal surface 11, and wiring layer 22 is formed on the second principal surface 12. The first principal surface 11 and the second principal surface 12 have a rectangular shape in this embodiment, but may have a circular shape. Note that a rectangular shape includes a square.

The glass substrate 10 has higher rigidity than that of a resin substrate. Therefore, even in the case where the respective areas of the first principal surface 11 and the second principal surface 12 are large, warpage can be reduced. The areas of the first principal surface 11 and the second principal surface 12 are, for example, 1.0×10² mm²−5.0×10⁵ mm², and preferably, 7.0×10³ mm²−3.0×10⁵ mm².

The glass material of the glass substrate 10 is not particularly limited, but is, for example, alkali-free glass, quartz glass, or photosensitive glass. The glass material of the glass substrate 10 preferably has an average coefficient of linear expansion at 5° C.-200° C. of 0.5×10⁶/° C.-13.0×10⁻⁶/° C. Should the average coefficient of the linear expansion be within the above range, detachment of the wiring layers 21 and 22 can be suppressed.

The average value d ave of the thickness d of the glass substrate 10 is, for example, 0.05 mm-2.0 mm. The smaller the d ave, the easier the holes 13 can be processed. The smaller the d ave, the thinner the semiconductor device can be. The d ave is preferably 0.1 mm-1.5 mm, more preferably, 0.2 mm-1.2 mm.

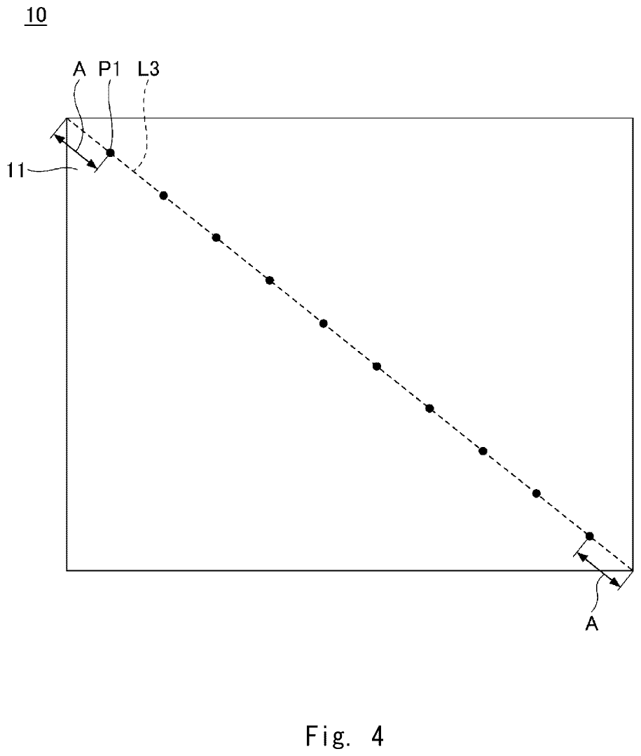

The thickness d of the glass substrate 10 is measured at, for example, ten measuring points P1 shown in FIG. 4. The ten measuring points P1 are arranged so as to divide the remaining range of a line segment L3 into nine equal parts, excluding a range A within 10 mm from both ends of the line segment L3. In the case where the first principal surface 11 has a rectangular shape, the line segment L3 is a diagonal line of the rectangle. In the case where the shape of the first principal surface 11 is a circle, the line segment L3 is equivalent to the diameter of the circle and passes through the orientation flat or notch of the glass substrate 10.

As shown in FIG. 3, the glass substrate 10 has the holes 13 formed on at least one of the first principal surface 11 and the second principal surface 12. The holes 13 are through holes formed through both the first principal surface 11 and the second principal surface 12 in this embodiment, but they may be non-through holes (bottomed holes) formed in only one of the first principal surface 11 and the second principal surface 12. Further, the holes 13 may have both through holes and non-through holes formed in combination.

Electrodes electrically connected to at least one of the wiring layer 21 and the wiring layer 22, for example, are to be embedded in at least one of the holes 13. In the case where the glass substrate 10 is used as an interposer, at least one of the holes 13 is a through hole, and a through electrode is to be embedded in the at least one through hole. The through electrode electrically connects the wiring layer 21 and the wiring layer 22.

Note that at least one of the holes 13 may be a dummy hole in which no electrode is to be embedded. A dummy hole is formed for the purpose of reducing the weight of the glass substrate 10 or preventing warpage of the glass substrate 10. In order to distinguish a hole in which an electrode is to be embedded from a dummy hole, it may hereinafter be referred to as an electrode hole.

In this embodiment, the holes 13 are a straight hole as shown in FIG. 3. Straight hole has a fixed diameter regardless of its depth from the first principal surface 11 or the second principal surface 12. The holes 13 may be a tapered hole. The tapered hole decreases in its diameter as the depth from the first principal surface 11 or the second principal surface 12 increases.

Although not shown, the holes 13 may be necked in the middle part thereof to form two tapered holes on the upper and the lower sides of the necked part. One tapered hole may decrease in its diameter as the depth from the first principal surface 11 increases. The other tapered hole decreases in its diameter as the depth from the second principal surface 12 increases. In addition, the holes 13 may be holes in which a tapered hole and a straight hole are formed in combination.

In the case where the holes 13 are a through hole and a straight hole, opening diameter D1 of the holes 13 in the first principal surface 11 and opening diameter D2 of the holes 13 in the second principal surface 12 are the same. Note that the holes 13 need not be a straight hole, and the opening diameter D1 and the opening diameter D2 need not be the same. Either of the opening diameter D1 and the opening diameter D2 may be larger.

The opening diameter D1 of the holes 13 in the first principal surface 11 is, for example, 10 μm-300 μm. The opening diameter D1 is preferably 20 μm-200 μm, more preferably 50 μm-100 μm. The holes 13 having different opening diameters D1 may be formed in combination in the first principal surface 11.

Similarly, the opening diameter D2 of the holes 13 in the second principal surface 12 is, for example, 10 μm-300 μm. The opening diameter D2 is preferably 20 μm-200 μm, more preferably 50 μm-100 μm. The holes 13 having different opening diameters D2 may be formed in combination in the second principal surface 12.

In both the first principal surface 11 and the second principal surface 12, the shape of the opening of the holes 13 is preferably circular from the viewpoint of workability. However, the shape of the opening of the holes 13 is not limited to a circular shape and may be elliptical or polygonal. The diameter of the opening of the holes 13 may be 10 μm-300 μm.

The ratio of the opening area of the holes 13 in the first principal surface 11 to the total area of the first principal surface 11 is, for example, 0.001%-90%, preferably 0.07%-80%, more preferably 0.75%-40%. Here, the total area of the first principal surface 11 includes both the area where there are no holes 13 and the area where the holes 13 are formed.

That is, the total area of the first principal surface 11 includes the opening area of the holes 13 in the first principal surface 11.

Similarly, the ratio of the opening area of the holes 13 in the second principal surface 12 to the total area of the second principal surface 12 is, for example, 0.001%-90%, preferably 0.07%-80%, and more preferably 0.75%-40%. Here, the total area of the second principal surface 12 includes both the area where there are no holes 13 and the area where the holes 13 are formed. In other words, the total area of the second principal surface 12 includes the opening area of the holes 13 in the second principal surface 12.

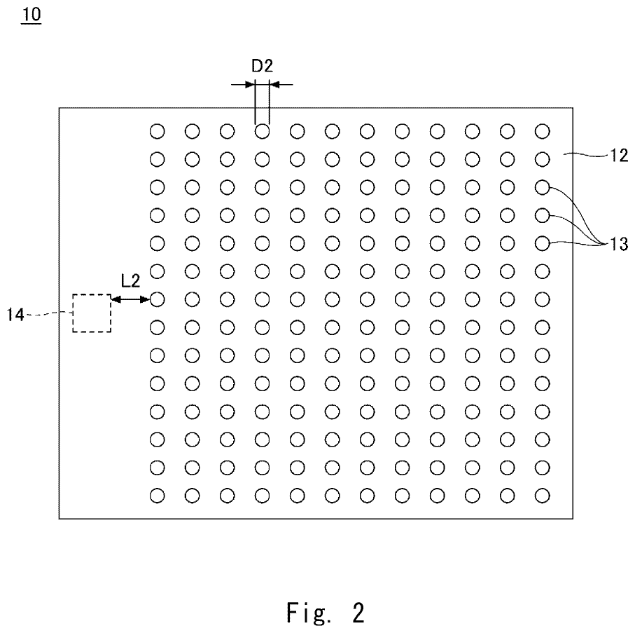

The number and arrangement of the holes 13 are not limited to those shown in FIGS. 1 and 2. The holes 13 are arranged in a matrix in FIGS. 1 and 2, but may be arranged in a staggered pattern or randomly. The number and arrangement of the holes 13, especially the number and arrangement of the electrode holes, are selected as appropriate according to the wiring patterns of the wiring layers 21 and 22.

The processing method of the holes 13 may be a general method, but in this embodiment, ablation processing is employed. In the ablation processing, the glass is locally evaporated or sublimated at the irradiation point of the laser beam, and the glass is locally removed. The generation of defects can be suppressed compared to the case of drilling. The defects are, for example, fractures or cracks.

The light source for ablation processing may be either a CW (continuous wave) laser or a pulse laser, but preferably a pulse laser. The pulse laser may be, for example, a CO₂ laser, a YAG laser, a UV laser, or an ArF excimer laser. The pulse laser may be a femtosecond laser or a picosecond laser.

The processing method of the holes 13 may be a general method as described above. For example, the processing method of the holes 13 may be drilling, etching, or blasting. Combination of laser processing and etching may be performed. A part of the glass substate is modified by performing laser processing to thereby form a modified part in the glass substrate, and etching is performed preferentially on the modified part.

Annealing may be performed after machining the holes 13. Annealing is a process of removing stress remaining in the glass substrate 10 by heating the glass substrate 10. Annealing may be performed after machining an identification mark 14, which will be described later. Either machining of the holes 13 or machining of the identification mark 14 may be performed first.

The glass substrate 10 has the identification mark 14 for identifying the glass substrate 10 between the first principal surface 11 and the second principal surface 12. The identification mark 14 is unique to each glass substrate 10. The identification mark 14 is a two-dimensional code in this embodiment. The two-dimensional code includes, for example, a QR code (registered trademark).

The identification mark 14 is not limited to two-dimensional codes. For example, the identification mark 14 may be a one-dimensional code, numbers, or characters. The identification mark 14 may be readable by a reader. The reader is provided facing the first principal surface 11 or the second principal surface 12.

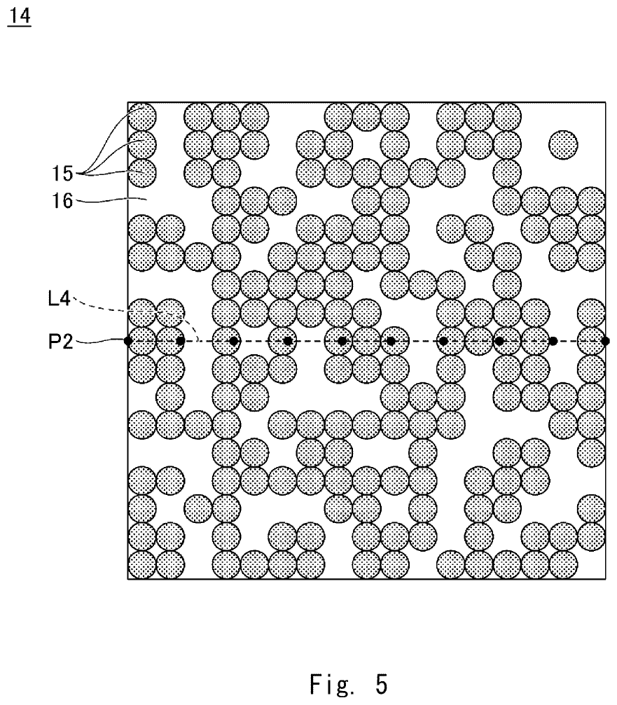

The identification mark 14 is represented by a pattern of modified parts 15 as shown in FIG. 5. The identification mark 14 is composed of the modified parts 15 and non-modified parts 16. The modified parts 15 are parts where the glass is modified. The modified parts 15 may include fine holes or fine cracks. Unlike the modified parts 15, the non-modified parts 16 are parts where the glass is not modified.

The processing method of the identification mark 14 may be a general method, and in this embodiment, laser processing is adopted. In the laser processing, a laser beam is focused and irradiated inside the glass substrate 10 to form the modified parts 15 inside the glass substrate 10. The modified parts 15 are parts where the laser beam is irradiated. The non-modified parts 16 are parts where the laser beam is not irradiated.

The light source for laser processing may be either a CW (continuous wave) laser or a pulse laser, but a pulse laser is preferred. The pulse laser is, for example, a CO₂ laser, a YAG laser, a UV laser, or an ArF excimer laser. The pulse laser may be a femtosecond laser or a picosecond laser.

The glass substrate 10 preferably meets all of the following requirements (A) to (C). The appearance of the glass substrate 10 and the readability of the identification mark 14 can be improved by forming the holes 13 and the identification mark 14 so that all of the following requirements (A) to (C) are met.

(A) The minimum value (Lmin) of the shortest distance (L1) between the identification mark 14 and the holes 13 when the first principal surface 11 is viewed from the front and the shortest distance (L2) between the identification mark 14 and the holes 13 when the second principal surface 12 is viewed from the front is equal to or greater than 100 μm.

In the case where L min is equal to or greater than 100 μm, since the identification mark 14 and the holes 13 are sufficiently distant from each other, the generation of defects can be suppressed during processing of the identification mark 14 or the holes 13, and the appearance of the glass substrate 10 and the readability of the identification mark 14 can be improved. The defects are, for example, fractures or cracks.

Lmin is preferably equal to or greater than 100 μm, more preferably, equal to or greater than 200 μm, and more preferably, equal to or greater than 1 mm. The larger L min, the better, but from the viewpoint of widening the effective area, Lmin is preferably equal to or smaller than 30 mm. Here, the effective area is an area for forming the holes 13. By widening the effective area, the number of the holes 13 can be increased.

(B) The ratio (d1 ave/d2 ave) of the average value (d1 ave) of the depth (d1) from the first principal surface 11 to the identification mark 14 to the average value (d2 ave) of the depth (d2) from the second principal surface 12 to the identification mark 14 is 0.03-33. That is, the following Expression (1) holds.

$$0.03 \leq d 1 ave / d 2 ave \leq 33. \qquad ( 1 )$$

Should Expression (1) holds, since the identification mark 14 and the surfaces of the glass substrate 10 (both the first principal surface 11 and the second principal surface 12) are sufficiently distant from each other, the generation of defects can be suppressed during processing of the identification mark 14, and the appearance of the glass substrate 10 and the readability of the identification mark 14 can be improved. d1 ave/d2 ave is preferably 0.03-33, more preferably 0.06-17, and more preferably 0.13-8.

(C) The ratio of the average value (d3 ave) of the thickness (d3) of the identification mark 14 to the average value (d ave) of the thickness (d) of the glass substrate 10 (d3 ave/d ave) is 0.01-0.50. In other words, the following Expression (2) holds.

$$0. 01 \leq d 3 ave / dave \leq 0.5 . \qquad ( 2 )$$

Should Expression (2) holds, since the identification mark 14 and the surfaces of the glass substrate 10 (both of the first principal surface 11 and the second principal surface 12) are sufficiently distant from 25 each other, the generation of defects during processing of the identification mark 14 can be suppressed, and the appearance of the glass substrate 10 and the readability of the identification mark 14 can be improved. d3 ave/d ave is preferably 0.01-0.50, and more preferably 0.10-0.30.

The glass substrate 10 preferably satisfies the following requirement (D) in addition to the aforementioned requirements (A) to (C). The readability of the identification mark 14 can be further improved by forming the holes 13 and the identification mark 14 so that the following requirement (D) is met in addition to the requirements (A) to (C) below.

(D) The ratio (Δd3/d3 ave) of the difference (Δd3=d3 max-d3 min) between the maximum value (d3 max) and the minimum value (d3 min) of the thickness (d3) of the identification mark 14 to the average value (d3 ave) of the thickness (d3) of the identification mark 14 is smaller than 0.50. In other words, the following Expression (3) holds.

$$Δ d 3 / d 3 ave < 0.5 . \qquad ( 3 )$$

Should Expression (3) hold, since the variation in the thickness of the identification mark 14 is sufficiently small, the readability of the identification mark 14 can be further improved. Δd3/d3 ave is preferably smaller than 0.50, and more preferably, equal to or smaller than 0.40. The smaller Δd3/d3 ave, the better, and it may be 0.00.

For example, d1, d2 and d3 are measured at the ten measuring points P2 shown in FIG. 5. When the first principal surface 11 is viewed from the front, the ten measuring points P2 are arranged so as to divide a line segment L4 into nine equal parts. The line segment L4 is set so as to pass through the center of the identification mark 14. In the case where the identification mark 14 has a rectangular shape when the first principal surface 11 is viewed from the front, the line segment L4 is set parallel to one side (preferably the long side) of the rectangle. In the case where the shape of the identification mark 14 is a circle when the first principal surface 11 is viewed from the front, the line segment L4 is equivalent to the diameter of the circle. The identification mark 14 is composed of the modified parts 15 and the non-modified parts 16 as described above. In the case where there is no modified part 15 at the measuring points P2 when the first principal surface 11 is viewed from the front, it is sufficient to measure d1, d2 and d3 of the modified parts 15 nearest to the measuring points P2.

### EXAMPLES

The experimental data will be described below.

In Example 1-1 to Example 1-7, glass substrates for semiconductors were fabricated under the same conditions except for the conditions shown in Table 1. Specifically, a glass substrate having 400,000 through holes was prepared, and a two-dimensional code was formed as an identification mark inside the prepared glass substrate. A glass material for the glass substrate was alkali-free glass. The first principal surface and the second principal surface were square with a side of 100 mm. A picosecond laser (manufactured by Photon Energy, Product Name: CEPHEUS 1016) with a wavelength of 1064 nm was used in the formation of an identification mark. The picosecond laser was oriented facing the first principal surface. An ArF excimer laser device (manufactured by Coherent, Product Name: LPX Pro 305) was used in the formation of through holes. The wavelength of the laser beam of this device was 193 nm, the maximum pulse energy was 0.6 J, the repetition frequency was 50 Hz, and the pulse width was 25 ns. A through hole extending from the first principal surface to the second principal surface was formed by irradiating a laser beam on the first principal surface of the glass substrate using the ArF excimer laser device. The through hole was a straight hole, and the opening of the through hole was circular. The average value Dave of the opening diameters D1 and D2 was 100 μm. Examples 1-1 to 1-4 are examples, and Examples 1-5 to 1-7 are comparative examples.

TABLE 1

| | d1ave | d2ave | d1ave/ | d3ave | Δd3/ | dave | d3ave/ | Dave | Lmin | Appearance | Reading |
|---|---|---|---|---|---|---|---|---|---|---|---|
| | [μm] | [μm] | d2ave | [μm] | d3ave | [μm] | dave | [μm] | [μm] | Inspection | Inspection |
| Example | 50 | 1900 | 0.03 | 50 | 0.20 | 2000 | 0.025 | 100 | 500 | ∘ | ∘ |
| 1-1 | | | | | | | | | | | |
| Example | 1920 | 60 | 32.00 | 20 | 0.40 | 2000 | 0.010 | 100 | 500 | ∘ | ∘ |
| 1-2 | | | | | | | | | | | |
| Example | 10 | 115 | 0.09 | 75 | 0.40 | 200 | 0.375 | 100 | 500 | ∘ | ∘ |
| 1-3 | | | | | | | | | | | |
| Example | 170 | 180 | 0.94 | 150 | 0.07 | 500 | 0.300 | 100 | 500 | ∘ | ∘ |
| 1-4 | | | | | | | | | | | |
| Example | 10 | 1940 | 0.01 | 50 | 0.60 | 2000 | 0.025 | 100 | 500 | x | x |
| 1-5 | | | | | | | | | | | |
| Example | 50 | 1900 | 0.03 | 50 | 0.20 | 2000 | 0.025 | 100 | 50 | x | x |
| 1-6 | | | | | | | | | | | |
| Example | 10 | 40 | 0.25 | 150 | 0.07 | 200 | 0.750 | 100 | 500 | x | x |
| 1-7 | | | | | | | | | | | |

In Examples 1-1 to 1-7, after identification mark was processed, appearance inspection and reading inspection were processed. Appearance inspection was performed under fluorescent light to visually check for defects. The defects are fractures or cracks. In the appearance inspection of Table 1, “o” indicates that there was no defect, and “x” indicates that there was a defect. In addition, in the reading inspection, it was checked whether the identification mark was readable by the reader (manufactured by Omron Corporation, Product Name: FQ2-CH10100N-M). In the reading inspection of Table 1, “o” indicates that the identification mark was readable, and “x” indicates that the identification mark was not readable.

As shown in Table 1, according to Examples 1-1 to 1-4, unlike Examples 1-5 to 1-7, all of the above requirements (A) to (C) were met, and the results of the appearance inspection and the reading inspection were satisfactory. In Table 1, the results of the appearance inspection and the reading inspection are the same, but according to the knowledge of the inventors of the present application, even if the results of the appearance inspection were good, that is, even if there is no problem in the visual check, the results of the reading inspection may be poor.

In Examples 2-1 to 2-7, glass substrates for semiconductors were fabricated under the same conditions except for the conditions shown in Table 2. Specifically, a glass substrate having 400,000 through holes was prepared, and a two-dimensional code was formed as identification mark inside the prepared glass substrate. A glass material for the glass substrate was quartz glass. The first principal surface and the second principal surface were square with a side of 100 mm. A THG (Third Harmonic Generation) laser (manufactured by OMRON LASERFRONT INC.) with a wavelength of 349 nm was used in the formation of an identification mark. The THG laser was oriented facing the first principal surface. An ArF excimer laser device (manufactured by Coherent, Product Name: LPX Pro 305) was used in the formation of through holes. The wavelength of the laser beam of this device was 193 nm, the maximum pulse energy was 0.6 J, the repetition frequency was 50 Hz, and the pulse width was 25 ns. A through hole extending from the first principal surface to the second principal surface was formed by irradiating a laser beam on the first principal surface of the glass substrate using the ArF excimer laser device. The through hole was a straight hole, and the opening of the through hole was circular. The average value Dave of the opening diameters D1 and D2 was 100 μm. Examples 2-1 to 2-4 are examples, and Examples 2-5 to 2-7 are comparative examples.

TABLE 2

| | d1ave | d2ave | d1ave/ | d3ave | Δd3/ | dave | d3ave/ | Dave | Lmin | Appearance | Reading |
|---|---|---|---|---|---|---|---|---|---|---|---|
| | [μm] | [μm] | d2ave | [μm] | d3ave | [μm] | dave | [μm] | [μm] | Inspection | Inspection |
| Example | 50 | 1900 | 0.03 | 50 | 0.20 | 2000 | 0.025 | 100 | 500 | ∘ | ∘ |
| 2-1 | | | | | | | | | | | |
| Example | 1920 | 60 | 32.00 | 20 | 0.40 | 2000 | 0.010 | 100 | 500 | ∘ | ∘ |
| 2-2 | | | | | | | | | | | |
| Example | 10 | 115 | 0.09 | 75 | 0.40 | 200 | 0.375 | 100 | 500 | ∘ | ∘ |
| 2-3 | | | | | | | | | | | |
| Example | 170 | 180 | 0.94 | 150 | 0.07 | 500 | 0.300 | 100 | 500 | ∘ | ∘ |
| 2-4 | | | | | | | | | | | |
| Example | 10 | 1940 | 0.01 | 50 | 0.60 | 2000 | 0.025 | 100 | 500 | x | x |
| 2-5 | | | | | | | | | | | |
| Example | 50 | 1900 | 0.03 | 50 | 0.20 | 2000 | 0.025 | 100 | 50 | x | x |
| 2-6 | | | | | | | | | | | |
| Example | 10 | 40 | 0.25 | 150 | 0.07 | 200 | 0.750 | 100 | 500 | x | x |
| 2-7 | | | | | | | | | | | |

In Example 2-1 to Example 2-7, after processing of the identification mark, appearance inspection and reading inspection were performed as in Example 1-1 to Example 1-7. In the appearance inspection of Table 2, “∘” indicates that there was no defect, and “×” indicates that there was a defect. In the reading inspection of Table 2, “∘” indicates that the identification mark was readable, and “×” indicates that the identification mark was not readable.

As shown in Table 2, in Example 2-1 to Example 2-4, unlike in Example 2-5 to Example 2-7, all of the above requirements (A) to (C) were met, and the results of the appearance inspection and the reading inspection were satisfactory. In Table 2, the results of the appearance inspection and the reading inspection are the same, but according to the knowledge of the present inventors, even if the results of the appearance inspection are satisfactory, that is, even if there is no problem in the visual inspection, the results of the reading inspection may be poor.

The glass substrate for semiconductors according to the present disclosure has been described above, but the present disclosure is not limited to the above embodiments. Various changes, modifications, substitutions, additions, deletions, and combinations are possible within the scope of claims. These also naturally fall within the technical scope of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A glass substrate for semiconductors comprising a first principal surface and a second principal surface disposed to face opposite the first principal surface, in which a wiring layer is to be formed on at least one of the first principal surface and the second principal surface, wherein
a hole is formed in at least one of the first principal surface and the second principal surface, and the glass substrate for semiconductors has an identification mark for identifying the glass substrate between the first principal surface and second principal surface,
the minimum value (Lmin) of a shortest distance (L1) between the identification mark and the hole when the first principal surface is viewed from the front and a shortest distance (L2) between the identification mark and the hole when the second principal surface is viewed from the front is equal to or greater than 100 μm,
a ratio (d1 ave/d2 ave) of the average value (d1 ave) of the depth (d1) from the first principal surface to the identification mark to the average value (d2 ave) of the depth (d2) from the second principal surface to the identification mark is 0.03-33, and
a ratio (d3 ave/d ave) of the average value (d3 ave) of the thickness (d3) of the identification mark to the average value (d ave) of the thickness (d) of the glass substrate is 0.01-0.50.

2. The glass substrate for semiconductors according to claim 1, wherein the ratio (Δd3/d3 ave) of the difference (Δd3=d3 max−d3 min) between the maximum value (d3 max) and the minimum value (d3 min) of the thickness (d3) of the identification mark to the average value (d3 ave) of the thickness (d3) of the identification mark is smaller than 0.50.

3. The glass substrate for semiconductors according to claim 1, wherein the average value (d ave) of the thickness (d) of the glass substrate is equal to or smaller than 2.0 mm.

4. The glass substrate for semiconductors according to claim 2, wherein the average value (d ave) of the thickness (d) of the glass substrate is equal to or smaller than 2.0 mm.
